(19) United States
(12) Patent Application Publication
(10) Pub. No.: US 2015/0024586 A1
(43) Pub. Date: Jan. 22, 2015

(54) METHOD FOR PRODUCING A MONOCRYSTALLINE METAL/SEMICONDUCTOR COMPOUND

(71) Applicant: FORSCHUNGSZENTRUM JUELICH GMBH, Juelich (DE)

(72) Inventors: Qing-Tai Zhao, Juelich (DE); Lars Knoll, Aachen (DE); Siegfried Mantl, Juelich (DE)

(21) Appl. No.: 14/375,909

(22) PCT Filed: Feb. 16, 2013
(86) PCT No.: PCT/DE2013/000087

§ 371 Date: Jul. 31, 2014

(30) Foreign Application Priority Data
Feb. 27, 2012 (DE) 10 2012 003 585.3

(51) Int. Cl. H01L 21/283

(52) U.S. Cl. CPC H01L 21/283
USPC 438/602

(57) ABSTRACT

In the method for producing a monocrystalline metal-semiconductor compound on the surface of a semiconducting functional layer, initially a supply layer comprising the metal is applied to the functional layer. Thereafter, the reaction between the metal and the functional layer is triggered by way of annealing. The supply layer ends at no greater than a layer thickness of 5 nm from the surface of the functional layer, or it transitions at no greater than this layer thickness into a region in which the metal diffuses more slowly than in the region that directly adjoins the functional layer. This measure advantageously allows diffusion flow of the metal into the functional layer to be prevented. This depends precisely on whether the metal-semiconductor compound is monocrystalline. The supply layer can comprise at least two layers made of the metal or an alloy of the metal, which are separated from each other by a diffusion barrier, but can also comprise a layer that is made of the metal and that directly adjoins the functional layer and at least one layer made of an alloy of the metal.

The invention relates to a method for producing a monocrystalline metal-semiconductor compound on the surface of a semiconducting functional layer.

### STATE OF THE ART

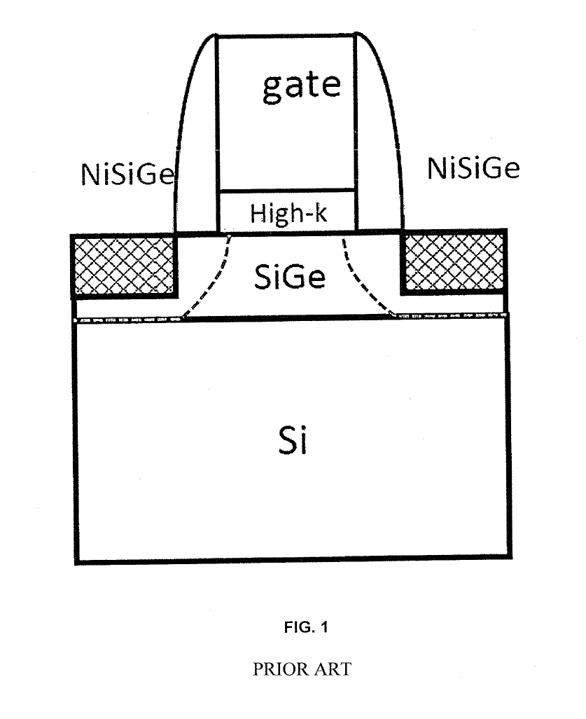

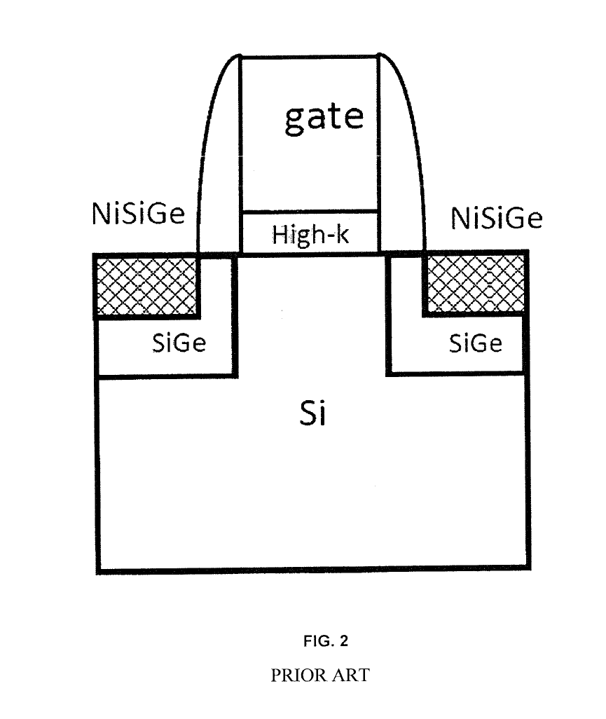

According to the present state of the art, silicides are the most widely used contact materials in CMOS transistors. They result from a reaction between the deposited metal and the silicon substrate. If semiconductor alloys of group 4A are to be used instead of silicon for novel electronic. and optoelectronic components, ternary and quaternary metals (M-) silicides/germanides (MSiGe, MGeSn, MSiSn, MSiGeC and the like) take the place of simple silicides. The reaction mechanisms are then considerably more complex. Islanding and germanium segregation occur after annealing steps during the silicidation of NiSiGe [see: J. Segera, S. L. Zhang, D. Mangelinck, and H. H. Radamson, Appl. Phys. Lett. 81 1978 (2002); and Q. T. Zhao, D. Buca, S. Lenk, R. Loo, M. Cayrnax, and S. Mantl, Microelectron. Eng. 76, 285 (2004)]. Due to the different reaction enthalpies, the layer thicknesses of the resulting silicides/germanides are not uniform and the interfaces are rough. FIG. 1 shows a cross-section of a typical Site MOSFET. FIG. 2 shows an example of a MOSFET comprising a strained channel using Site as the source/drain material. NiSiGe layers are used as the contact metal in the examples of FIGS. 1 and 2. The rough interface between the metal and semiconductor worsens the properties of the transistors from FIGS. 1 and 2 and causes leakage currents, high contact resistance and low thermal stability.

It is therefore of great importance to produce silicides and germanides as uniformly as possible with atomically flat interfaces to group IV semiconductor alloys and to increase thermal stability.

In the publications by [L. J. Jin, K. L. Fey, W. K. Choi, E. A. Fitzgerald, D. A. Antoniadis, A. J. Pitera, M. L. Lee, D. Z. Chi, M. A. Rahman, T. Osipowicz, and C. H. Tung, J. Appl. Phys. 96, 033520 (2005); L. J. Jin, K. L. Fey, W. K. Choi, E. A. Fitzgerald, D. A. Antoniadis, A. J. Pitera, M. L. Lee, and C. H. Tung, J. Appl. Phys. 97, 104917 (2005)], an Ni—Pt or Ni—Pd alloy is produced by the addition of elements such as Pt or Pd. The morphology and thermal stability of Ni(Pt)SiGe or Ni(Pd)SiGe is improved compared to NiSiGe. The resulting silicide/germanide layers are nonetheless polycrystalline.

Compared to polycrystalline layers, epitactic silicides and germanides are advantageous given the substantially perfect interfaces and absence of grain boundaries, while offering high thermal stability at the same time. The difficulty in production is that they typically crystallize in the orthorhombic phase on semiconductor alloys comprising elements from group 4A. The publication by [B. Zhang, W. Yu, Q. T Zhao, G. Mussler, L. Jin, D. Buca, B. Hollander, J. M. Hartmann, M. Zhang, X. Wang and S. Mantl, Appl. Phys. Lett. 98, 252101 , (2011)] shows epitactic Ni(Al)Si_{0.7}Ge_{0.3}, which was created by annealing Ni/Al on relaxed SiGe. However, the temperature required for this purpose is more than 600° C., and consequently above a suitable temperature range for strained SiGe. High temperatures cause stress relaxation and undesirable outward Ge diffusion, in particular in SiGe having a high content of Ge.

### PROBLEM AND SOLUTION

Therefore, it is the object of the invention to provide a method which allows high-quality monocrystalline metal-semiconductor compounds to be produced on a semiconducting functional layer even at lower temperatures.

These objects are achieved according to the invention by a method according to the main claim. Further advantageous embodiments will be apparent from the dependent claims referring back to the main claim.

### SUBJECT MATTER OF THE INVENTION

Within the scope of the invention, a method for producing a monocrystalline metal-semiconductor compound on the surface of a semiconducting functional layer was developed. Initially, a supply layer comprising the metal is applied to the functional layer. Thereafter, the reaction between the metal and the functional layer is triggered by way of annealing.

According to the invention, the supply layer ends at no greater than a layer thickness of 5 nm from the surface of the functional layer, and preferably at no greater than a layer thickness of 3 nm from the surface of the functional layer, or transitions at no greater than this layer thickness into a region in which the metal diffuses more slowly than in the region that directly adjoins the functional layer.

It was recognized that the layer thickness plays a decisive role for the diffusion flow (amount of substance per unit of time) of the metal into the zone in which the metal reacts with the semiconducting material of the functional layer. If the supply layer ends at no greater than the claimed layer thickness, only as much metal diffuses as can be converted during the reaction with the semiconducting material. The metal is thus converted substantially exclusively into the desired monocrystalline metal-semiconductor compound. In contrast, if the layer is thicker, an excess supply of the metal is created in the reaction zone. This results in the formation of grains having differing sizes and orientations, which consequently also grow at differing rates. Moreover, the strain can accidentally discharge if too much metal diffuses into the reaction zone per unit of time, for example, if the functional layer is strained with respect to the substrate to which it is applied.

The diffusion flow of the metal is substantially determined by the thickness of the region of the supply layer which directly adjoins the functional layer. The diffusion flow from a particular location in the supply layer to the functional layer drops exponentially with the distance between this location and the functional layer. The influence of the local permeability of the supply layer, with respect to the metal diffusing to the functional layer, on the entire diffusion flow from the supply layer into the functional layer, therefore also diminishes as the distance between the observed test point and the functional layer increases.

Since the supply layer ends at no greater than the claimed layer thickness, a boundary is also set for the total amount of metal that can be used for forming the metal-semiconductor compound. It was recognized that this also constitutes an advantage with respect to the quality of the metal-semiconductor compound. The less total metal is converted into the metal-semiconductor compound, the sooner the reaction resulting in the metal-semiconductor compound is completed during annealing. If annealing is continued, the metal-semiconductor layer does not become thicker, but organized. In particular, rough areas are leveled out because these have a higher potential energy than a planar surface. If further metal is added by diffusion, this organization process is interrupted. If the diffusion flow of the metal increases, a point is eventually reached at which the deposition of this newly added metal on larger grains is energetically favored over layer organization, so that the quality of the produced metal-semiconductor layer deteriorates.

However, the supply layer need not end at the claimed layer thickness, but alternatively can also transition into a region in which the metal diffuses more slowly. A larger overall amount of the metal can then be stored in the supply layer, without an impermissibly high amount of metal diffusing from the supply layer into the functional layer per unit of time.

In a particularly advantageous embodiment of the invention, the supply layer for this purpose comprises at least two layers made of the metal, an alloy of the metal, or a compound of the metal, which are separated from each other by a diffusion barrier. In the diffusion barrier, the atoms of the metal diffuse more slowly than within the metal or in the alloy. In particular aluminum, an oxide or a nitride is suitable as the diffusion barrier. Even an ultrathin (<1 nm) oxide or nitride layer can suffice. The alloy and compound of the metal differ qualitatively in the actions thereof as a supply layer, in that the metal tends to be bound more weakly in an alloy than in a compound. As a result, less activation energy, and thus a lower temperature, are required to excite the metal from an alloy to diffuse toward the functional layer.

In a further particularly advantageous embodiment of the invention, the supply layer has a multi-layer structure, in which, in each case
a layer made of the metal, an alloy of the metal, or a compound of the metal, and
a diffusion barrier
   alternate. Advantageously one of the layers made of the metal, an alloy of the metal, or a compound of the metal, adjoins the surface of the semiconducting functional layer.

It was found in the experiments conducted by the inventors, that an excess supply of metal crowding around a single diffusion barrier can overwhelm this barrier. The barrier then ultimately loses the action thereof, so that the behavior of the supply layer again approaches the behavior of a thick supply layer according to the prior art. By designing the supply layer as a multi-layer structure, each of the at least two diffusion barriers always separates only small amounts of metal from each other, in this way, a large amount of metal can be accommodated in total in the supply layer, and an accordingly thick metal-semiconductor contact can be implemented, while control is maintained over the diffusion flow in the zone in which the metal reacts with the semiconducting material of the functional layer. This controlled diffusion flow ensures the formation of a high quality metal-semiconductor compound.

In a further advantageous embodiment of the invention, a portion of the material of at least one diffusion barrier diffuses at the interface between the supply layer and the semiconducting functional layer, where the material catalyzes the formation of the metal-semiconductor compound. Since the catalyst is not consumed, only a minute portion of the material of the diffusion barrier is required, whereby the function of the diffusion barrier is preserved.

In a further advantageous embodiment of the invention, the supply layer comprises a layer that is made of the metal directly adjoining the functional layer and at least one layer made of an alloy of the metal. In any alloy of the metal, the atoms of the metal diffuse more slowly than in the pure metal. The transition from pure metal to the alloy is thus easier to implement in the creation of the functional layer than the incorporation of a diffusion barrier, which physically and chemically differs significantly from the remaining material of the supply layer. In particular one or more metals from the group Al, Co, Cr, Pd, Pt, Ti and W are suitable as an additional alloying element in addition to the metal, which is intended to form the metal-semiconductor compound. These metals are particularly compatible with silicon technology, because they diffuse only slowly in silicon and consequently do not impair the functional layer. The alloy of the metal can be regarded as a borderline case of a multi-layer structure having infinitely thin individual layers made of the metal and the additional alloying element as a diffusion barrier.

In a particularly advantageous embodiment of the invention, a stoichiometry of one metal atom to one formula unit of the semiconductor, which is to say SiNi or GeSiNi, for example, is established for the metal-semiconductor compound. In this stoichiometry, the metal-semiconductor compound has considerably better electrical conductivity than that of one metal atom to two formula units of the semiconductor, which is to say NiSi₂, for example. The metal-semiconductor compound is moreover considerably better suited as a contact for the integration of a semiconductor component into electronic circuits. Here, one accepts that the lattice matching of the compound to the functional layer in this stoichiometry is inferior to that with two formula units of the semiconductor per metal atom, and that the compound consequently responds more sensitively to excessively high diffusion flow of the metal during annealing. But because this diffusion flow is more controllable by virtue of the measures according to the invention, inferior lattice matching ceases to be a drawback, Despite isolated dislocations and grain boundaries, the structural and electrical properties of the monocrystalline layers produced by way of the method according to the invention are superior to the previously known polycrystalline layers.

The stoichiometry of one metal atom to one formula unit of the semiconductor provides the added advantage that this is established at lower temperatures during annealing than the stoichiometry of one metal atom to two formula units of the semiconductor. Thus, there is a decreased risk of the primary structure and function of the functional layer being impaired during annealing.

This applies in particular in a further particularly advantageous embodiment of the invention, in which the functional layer is strained with respect to the substrate on which it has grown. As the temperature rises, the likelihood that the strain relaxes locally increases exponentially.

Advantageously, a semiconductor alloy is selected as the semiconducting material for the functional layer, in particular a semiconductor alloy comprising only elements from group 4A, and here in particular a semiconductor alloy from the group SiGe, GeSn, SiSn, SiGeC, SiC, SiGeSn, SiGeCSn or SiCSn. These alloys are particularly suitable for use in electronic and optoelectronic components. For example, monocrystalline SiGe is used in complementary metal-oxide-semiconductor (CMOS) transistors for source and drain contact. The uniaxial compressive strain caused in the silicon channel thereby increases the hole mobility. Moreover, Site can also be used directly in the channel due to the higher hole mobility. GeSn and SiGeSn can be used for optical components. According to the existing state of the art, however, the integration of components into electronic circuits for which the source and drain must be electrically contacted posed a constraint in terms of technological implementation. The method according to the invention can be used to produce silicides and germanides having low contact resistances, good electrical conductivity, and abrupt as well as uniform interfaces to the semiconductor.

Advantageously, the portion of the supply layer that has not reacted with the functional layer is removed by way of chemically selective etching after annealing. The metal-semiconductor compound produced according to the invention is then exposed and can be used an electrical contact.

Annealing can be carried out, for example, using rapid thermal annealing (RTA), furnace annealing, laser annealing, microwave annealing or flash lamp annealing.

After the metal-semiconductor compound has been formed, advantageously further metal can be grown thereon in a monocrystalline manner as the metallic functional layer.

### SPECIFIC DESCRIPTION

The subject matter of the invention will be described hereafter based on figures, without thereby limiting the subject matter of the invention. In the drawings:

FIG. 1: (prior art) shows the cross-section of a typical SiGe MOSFET transistor;

FIG. 2: (prior art) shows a MOSFET comprising a strained channel;

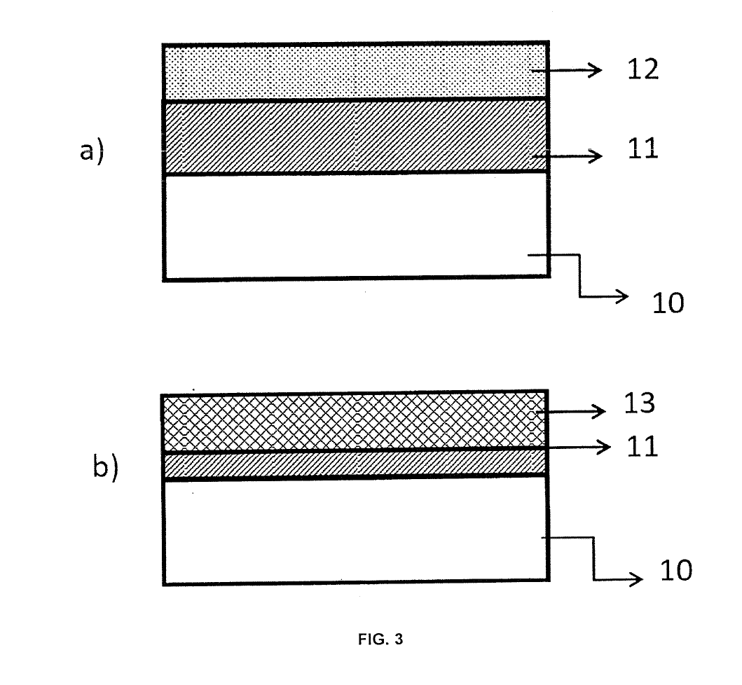

FIG. 3: shows the limitation of the diffusion flow by an ultrathin supply layer;

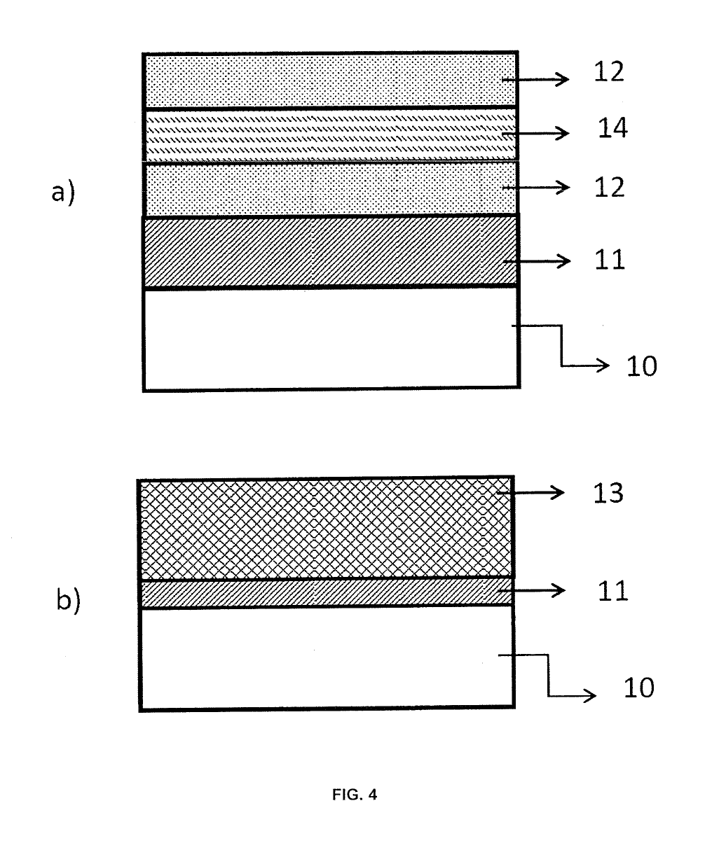

FIG. 4: shows the limitation of the diffusion flow by a diffusion barrier in the supply layer; and

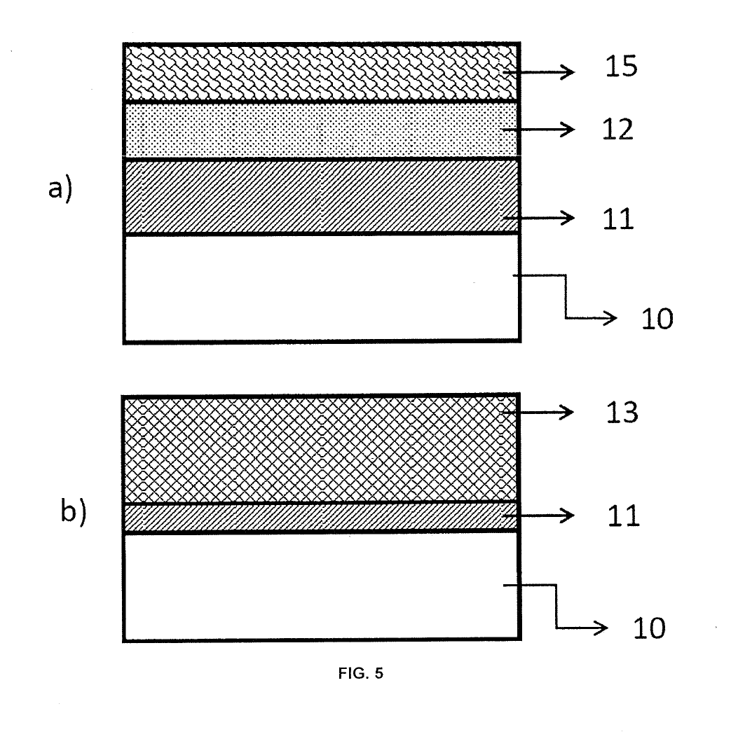

FIG. 5: shows the limitation of the diffusion flow by a supply layer, which is composed of a pure metal layer and a layer comprising an alloy of the metal provided thereabove.

FIG. 3 shows the production of a thin monocrystalline silicide/germanide layer (NiSiGe on SiGe). For this purpose, initially a very thin metal layer 12 (such as Ni) having a thickness of less than 5 nm is deposited onto an alloyed semiconductor 11 (such as Si₁₋ₓGeₓ), which, in turn, was previously deposited onto a substrate 10 (such as silicon) (FIG. 3a). This can take place by way of thermal evaporation or, as is preferred industrially, by way of cathode sputtering (sputtering). In this example, a quartz lamp furnace (rapid thermal processor, RTP) was employed, and what is known as “spike annealing” (which is to say, a maximal temperature dwell time of <1 second) was carried out at a spike temperature of 600° C. As an alternative, annealing can be carried out at 450° C. for a duration of several minutes. During annealing, the metal layer 12 and a portion of the functional layer 11 react to form monocrystalline NiSiGe 13 (FIG. 3b).

FIG. 4 shows the production of a monocrystalline silicide/germanide layer (such as NiSiGe on SiGe) from a supply layer, which is a multi-layer system comprising different metals. An intermediate layer 14, such as aluminum, is deposited between the two metal layers 12 (such as Ni), from which metal is to diffuse into the functional layer 11 and react there (FIG. 4a). The first metal layer 12, which is applied directly to the alloyed semiconductor 11 (such as Si₁₋ₓGeₓ), has a thickness of less than 5 nm. At the beginning of the annealing process, initially only Ni reacts with Si₁₋ₓGeₓ and monocrystalline NiSi₁₋ₓₗGeₓ 13 is created (FIG. 4b). The Al intermediate layer is a diffusion barrier and makes the diffusion of Ni of the upper Ni layer into the functional layer 11 more difficult. In the further course of the annealing process, the Ni atoms of the upper Ni layer diffuse through the Al in the direction of the functional layer 11, and the original NiSi₁₋ₓGeₓ layer 13, which serves as a seed crystal, grows. Al diffuses to the surface and can be selectively removed using a wet-chemical process.

FIG. 5 shows a further exemplary embodiment of the method according to the invention, in which monocrystalline silicide/germanide layers are produced on a semiconducting functional layer 11 using a supply layer, which comprises a thin metal layer 12 and a layer 15 made of a metal alloy. The alloyed semiconductor 11 is monocrystalline SiGe on a Si substrate 10, and the metal layer 12 is nickel. The metal alloy 15 likewise comprises nickel and additionally one further metal, such as one from the group Al, Co, Cr, Pd, Pt, Ti, W (FIG. 54 The essential matter is that the presence of the further metal makes the diffusion of nick& from the alloy 15 more difficult, so that during annealing the overall diffusion flow of nick& into the functional layer 11 remains limited and crystalline NiSiGe 13 on Site 11 is formed (FIG. 5b).

1. A method for producing a monocrystalline metal-semiconductor compound on the surface of a semiconducting functional layer, wherein a supply layer comprising the metal is initially applied to the functional layer, and subsequently the reaction between the metal and the functional layer is triggered by way of annealing, wherein the supply layer either ends at no greater than a layer thickness of 5 nm from the surface of the functional layer, or transitions into a region in which the metal diffuses more slowly than in the region that directly adjoins the functional layer.

2. The method according to claim 1, wherein a semiconductor alloy is selected as the semiconductor.

3. The method according to claim 2, wherein the semiconductor alloy only comprises elements from group 4A.

4. The method according to claim 3, wherein a semiconductor alloy from the group SiGe, GeSn, SiSn, SiGeC, SiC, SiGeSn, SiGeCSn or SiCSn is selected.

5. The method according to claim 1, wherein the supply layer either ends at no greater than a layer thickness of 3 nm from the surface of the functional layer or transitions into a region in which the metal diffuses more slowly than in the region that directly adjoins the functional layer.

6. The method according to claim 1, wherein the supply layer comprises at least two layers made of the metal, an alloy of the metal, or a compound of the metal, which are separated from each other by a diffusion barrier.

7. The method according to claim 6, wherein the supply layer has a multi-layer structure, in which in each case
a layer made of the metal, an alloy of the metal, or a compound of the metal, and
a diffusion barrier
alternate.

8. The method according to claim 6, wherein aluminum, an oxide or a nitride is selected as the diffusion barrier.

9. The method according to claim 6, wherein a portion of the material of at least one diffusion barrier diffuses at the interface between the supply layer and the semiconducting functional layer, where this material catalyzes the formation of the metal -semiconductor compound.

10. The method according to claim 1, wherein that the supply layer comprises a layer that is made of the metal. and directly adjoins the functional layer and at least one layer made of an alloy of the metal.

11. The method according to claim 10, wherein one or more metals from the group Al, Co, Cr, Pd, Pt, Ti, W are selected as the additional alloying element.

12. The method according to claim 1, wherein a stoichiometry of one metal atom to one formula unit of the semiconductor is established for the metal-semiconductor compound.

13. A method according to claim 1, wherein a functional layer is selected, which is strained with respect to the substrate on which it has grown.

14. The method according to claim 1, wherein the portion of the supply layer that has not reacted with the functional layer is removed by way of chemically selective etching after annealing.
